(19) United States
(12) Patent Application Publication
(10) Pub. No.: US 2011/0272011 A1
(43) Pub. Date: Nov. 10, 2011

(54) Solar Cell

(75) Inventors: Anthony Lochtefeld, Ipswich, MA (US); Allen Barnett, Landenberg, PA (US)

(73) Assignee: AMBERWAVE, INC., Salem, NH (US)

(21) Appl. No.: 12/795,207

(22) Filed: Jun. 7, 2010

Related U.S. Application Data
(60) Provisional application No. 61/184,653, filed on Jun. 5, 2009.
(60) Provisional application No. 61/244,579, filed on Sep. 22, 2009.

(51) Int. Cl. H01L 31/06; H01L 31/18

(52) U.S. Cl. 136/255; 438/72; 257/E31.12

(57) ABSTRACT

A device, system, and method for a thin Si solar cell with epitaxial lateral overgrowth (ELO) structure described in may demonstrate higher open circuit voltage are disclosed herein. An exemplary thin silicon solar cell structure has a p+ silicon substrate. A dielectric layer is disposed over the p+ silicon substrate. One or more trenches are defined within the dielectric layer. A thin n type silicon layer is grown on the p+ silicon substrate within the trench by epitaxial lateral overgrowth wherein a junction area of the solar cell is minimized.

### RELATED APPLICATIONS

This application claims the benefit of and priority to U.S. Provisional Application Ser. No. 61/184,653 filed Jun. 5, 2009, and U.S. Provisional Application Ser. No. 61/244,579 filed Sep. 22, 2009 the disclosures of which are hereby incorporated by reference in its entirety.

### TECHNICAL FIELD

The present invention relates to solar cells and more particularly, relates to thin film solar cells.

### SUMMARY

The present invention is a novel device, system, and method for a thin silicon solar cell with epitaxial lateral overgrowth (ELO) structure. An exemplary thin silicon solar cell structure has a p+ silicon substrate and a dielectric layer disposed over the p+ silicon substrate. One or more trenches are defined within the dielectric layer. A thin n type silicon layer is grown on the p+ silicon substrate within the trench by epitaxial lateral overgrowth wherein a junction area of the solar cell is minimized within the trench.

The present invention is not intended to be limited to a system or method that must satisfy one or more of any stated objects or features of the invention. It is also important to note that the present invention is not limited to the exemplary or primary embodiments described herein. Modifications and substitutions by one of ordinary skill in the art are considered to be within the scope of the present invention, which is not to be limited except by the following claims.

### BRIEF DESCRIPTION OF THE DRAWINGS

These and other features and advantages of the present invention will be better understood by reading the following detailed description, taken together with the drawings wherein:

FIG. 1 is a graph of V_{oc} as a function of device thickness, surface recombination velocities and light trapping according to a first exemplary embodiment of the invention.

FIG. 2 is a graph of the efficiency as a function of device thickness, bulk lifetime and light trapping according to the first exemplary embodiment of the invention.

FIG. 3 is an exemplary structure of each processing step according to the first exemplary embodiment of the invention.

FIG. 4 is an exemplary structure after completion of step 5 with epitaxial lateral overgrowth according to the first exemplary embodiment of the invention.

FIG. 5a-f are photographs of six different exemplary patterns after the Si growth according to the first exemplary embodiment of the invention.

FIG. 6 is an exemplary mask used for a star pattern according to the first exemplary embodiment of the invention.

FIG. 7 is a microscope picture after ELO growth according to the first exemplary embodiment of the invention.

FIG. 8A is microscope picture for region 1 on horizontal pattern before Epitaxial Lateral Overgrowth (ELO) growth according to the first exemplary embodiment of the invention.

FIG. 8B is microscope picture for region 1 on horizontal pattern after Epitaxial Lateral Overgrowth (ELO) growth according to the first exemplary embodiment of the invention.

FIG. 9 is a top view of a quarter of 8 inch wafer after ELO growth according to the first exemplary embodiment of the invention.

FIG. 10 is a Scanning Electron Microscopy (SEM) after ELO growth according to the first exemplary embodiment of the invention.

FIGS. 11A and 11B are cross section view of various exemplary SOI thin silicon solar cell structures according to a second exemplary embodiment of the invention.

FIG. 12 is an exemplary SOI thin silicon solar cell structure according to the second exemplary embodiment of the invention.

FIG. 13 is an exemplary SOI thin silicon solar cell structure top view of patterned active areas and top contact according to the second exemplary embodiment of the invention.

FIG. 14A-D are an exemplary grid patterns with different active area coverage according to the second exemplary embodiment of the invention.

FIG. 15A is an exemplary planar cell with 100% coverage according to the second exemplary embodiment of the invention.

FIG. 15B is an exemplary grid cell according to the second exemplary embodiment of the invention.

FIG. 16 is EQE for different active area coverage according to the second exemplary embodiment of the invention.

FIG. 17 is long wavelength EQE for different active area coverage according to the second exemplary embodiment of the invention.

FIG. 18 is the I-V response of fabricated epi-SOI solar cells for different active area coverage according to the second exemplary embodiment of the invention.

### DETAILED DESCRIPTION OF THE PREFERRED EMBODIMENTS

According to a first exemplary embodiment, thin Si solar cell with epitaxial lateral overgrowth (ELO) structure described herein may demonstrate higher open circuit voltage (V_{oc}) . According to simulation results, high voltage can be obtained even without light trapping on the backside of the thin Si layer. Thin n type silicon layer has been grown on p+ Si substrate using a method of epitaxial lateral overgrowth by Chemical Vapor Deposition (CVD). A scanning electron microscopy (SEM) has been used to show the dimension of the pn junction region and light generation region after the n type Si growth.

Open circuit voltage (V_{oc}) is an important parameter in determining the performance of a solar cell [1]. The first exemplary embodiment utilizes the Epitaxial Lateral Overgrowth (ELO) to obtain a thin crystalline n type Si layer on a highly doped p type (100) orientated Si substrate. The thin Si has been grown by CVD out of line patterns with different line widths, spacing and orientations, using thermally-grown SiO₂ as the mask. The thin crystalline n type Si layer may be continuous or non-continuous according to various different embodiment of the invention.

Compared with the normal thin Si solar cells [3] having the same light generation area, this structure may be used to provide a smaller junction areas which can lower the saturation current and should result in higher V_{oc}. Meanwhile, the planar Si solar cells have also been fabricated on the same substrate. The open circuit voltage is analyzed and compared among different thin Si solar cells using the same Si substrate.

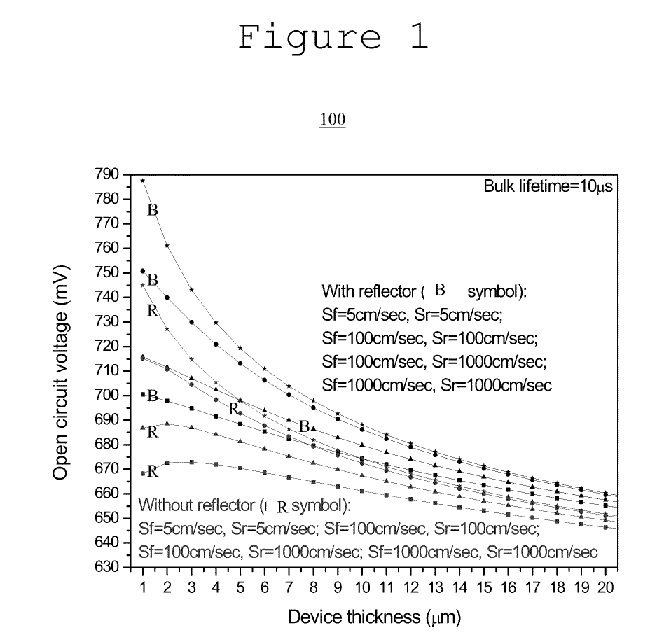

Referring to FIG. 1, the V_{oc} is a function of absorber thickness, surface recombination velocities and light trapping. The reflector is between the epi layer and the substrate. It has been reported that an internal reflectance of approximately 80% has been achieved for a porous Si stack of 15 layers [4]. In this simulation, a perfect light trapping is assumed for one case. From FIG. 1, it can be seen that the improvement in open-circuit voltage is greater as the absorber thickness decreases gradually from 20 μm. The V_{oc} is 688 mV with light trapping and 674 mV without back reflector at 10 μm absorber thickness, when the surface recombination velocities are 5 cm/sec and the bulk lifetime of the thin Si layer is 10 μs. So high V_{oc} can be still obtained without a reflector. V_{oc} may become more sensitive to light trapping and surface recombination as absorber thickness is less than 5 μm. V_{oc} may be less affected by moderate surface recombination as the absorber thickness gets close to 20 μm.

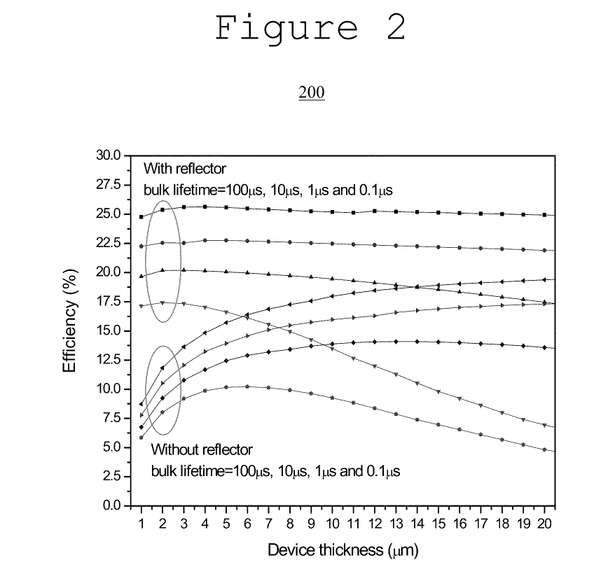

Referring to FIG. 2, the efficiency is a function of the absorber thickness, bulk lifetime and light trapping. There are two cases, one with perfect light trapping and one without back reflector. FIG. 2 depicts the importance of light trapping for thin silicon solar cell. At 10 μm absorber thickness, the efficiency is 22.4% with a perfect light trapping and 15.9% without a back reflector, when the bulk lifetime of the thin Si layer is 10 μs and surface recombination velocities are 5 cm/sec.

For each case, the increase of bulk lifetime from 10 μs to 100 μs may give roughly a 2.5% improvement in efficiency. But perfect light trapping may give roughly a 4-7% increase in efficiency, when the bulk lifetime is 10 μs and 100 μs respectively and the absorber thickness is between 10 μm and 20 μm. High efficiency can be achieved for a thin silicon solar cell with reduced minority carrier lifetime. For a minority carrier lifetime of 10 μs, an efficiency of 22% can be achieved for a thin silicon solar cell.

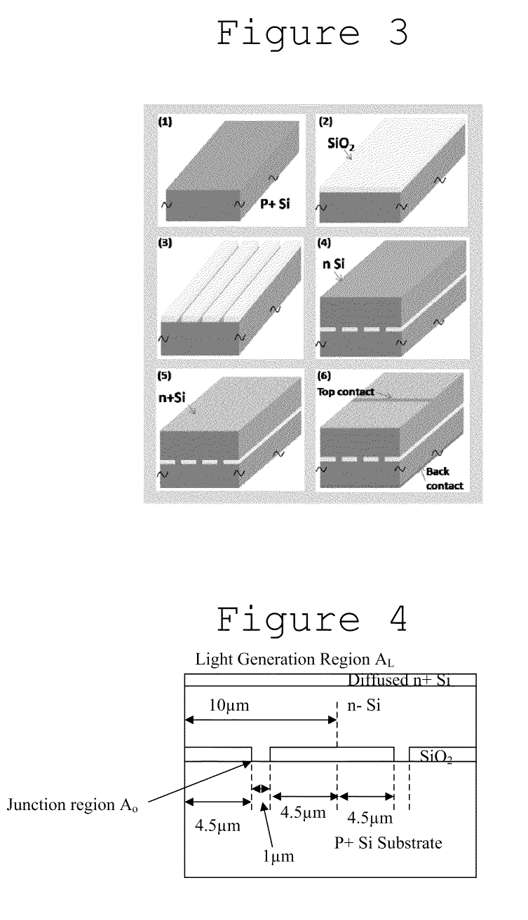

Referring to FIG. 3 an exemplary structure is shown in each processing step.

Step (1): P+, (100) oriented Si wafer may be the substrate.

Step (2): A 800 nm SiO2 layer may be thermally grown on the substrate.

Step (3): Utilizing photolithography, different patterns may be defined. The patterns may have different geometries. In the drawing, we use line pattern for an example. The SiO2 in the opening may be etched off in 5:1 buffered oxide etch (BOE).

Step (4): After the cleaning of the patterned surface, n type thin silicon may be grown by CVD using the method of epitaxial lateral overgrowth.

Step (5): A POCl3 diffusion forms an n+ region to the n type Si surface.

Step (6) : The back contact Al may be evaporated by e-beam and then annealed in tube furnace. Finally, the top contact Ti/Pd/Ag (20 nm/20 nm/1000 nm) may be evaporated by e-beam. A double layer antireflection coating may be deposited on the device.

Referring to FIG. 4, the cross section view with dimensions is shown for the structure in step (5). The line width is fpm and the line spacing is 10 μm. The ratio of light generation area to junction area is 10. According to the equations (1), the theoretical increase of open circuit voltage is around 59.4 mV compared with the usual structure for which the light generation region area is the same as the junction region area.

$$Voc = \frac{kT}{q} ln ( \frac{{A}_{L} {J}_{L}}{{A}_{0} {J}_{0}} + 1 )$$

Therefore, by using the exemplary structure, significant improvement in open circuit voltage can be achieved. The ratio of light generation region area to junction area can be designed larger to have greater improvement in V_{oc}. To realize this structure, the processing may utilize photolithography, epitaxial lateral overgrowth and basic silicon solar cell processing technique.

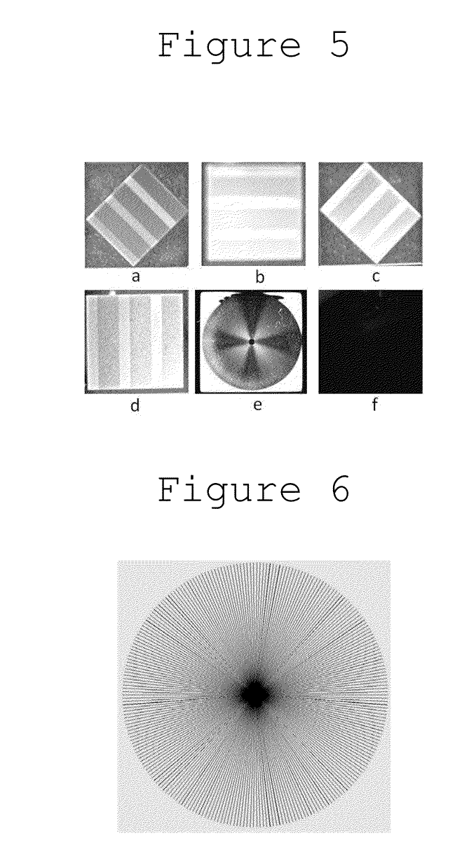

Referring to FIG. 5, after the thin Si growth on different line patterns that are on the same Si substrate are shown in photographs. The size of each square is about 1 cm×1 cm. The patterns include diagonal (a) and (c), horizontal (b), vertical (d), star (e) and full Si without ELO (f) pattern. The oxide openings, before Si growth on each of the patterns ((a), (b), (c) and (d)), are 1 μm, 2 μm and 3 μm wide; for each line width, there are 10 μm and 20 μm line spacing, from the center to center of each line. On the star pattern, the line width is 1 μm.

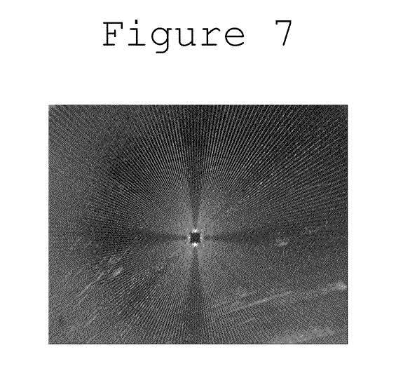

The star pattern (e) provides information on the degree of lateral over growth and quality of growth on each direction. For the mask used which is shown in FIG. 6, the lines in each direction are 1 μm wide and the star is confined in a 1 cm×1 cm square. Si starts to grow from the 1 μm lines. From the microscope pictures in FIG. 7, the growth is different on different direction is shown. There is less lateral overgrowth on the vertical and horizontal pattern.

Based on the growth results from star pattern, patterns may be designed having different orientations on the same wafer to get different lateral overgrowth. In this case, different ratios of light generation area to junction area can be obtained after a single Si growth. FIG. 7 also shows that in the regions at oblique angles and close to the center, Si is almost continuous; moving further away from the center, Si is not continuous. Accordingly, solar cells may be made from continuous and non continuous Si, depending on the spacing between the openings in the oxide mask.

For the horizontal pattern (b), there are six regions shown. After etching off the oxide in step (3), the line dimension for each region (from top to bottom) is shown in the following table 1.

TABLE 1
Dimension for each region on horizontal pattern (b)

| | Line width | Lines pacing |
|---|---|---|
| Region | (μm) | (μm) |
| 1 | 1 | 10 |
| 2 | 1 | 20 |
| 3 | 2 | 10 |
| 4 | 2 | 20 |
| 5 | 3 | 10 |
| 6 | 3 | 20 |

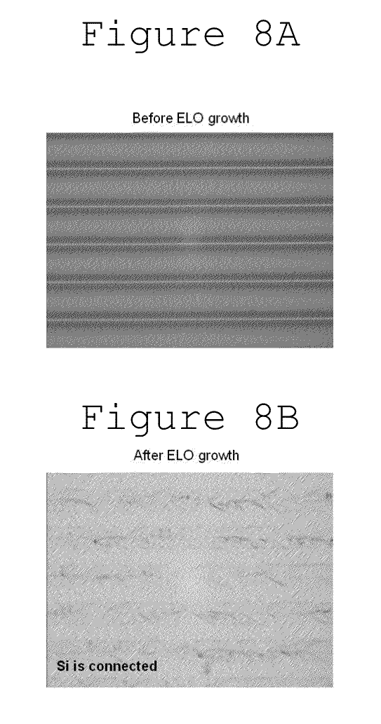

The vertical and diagonal patterns also have the six regions, but have different orientations of the lines. FIG. 8 shows microscope pictures for region 1 on pattern (b) before and after ELO growth. For the pictures taken before ELO growth, the oxide in the opening is etched off.

In the pictures before ELO growth, the white lines are openings in oxide, where Si may first start to grow. In the pictures after ELO growth, the white part is grown Si. Si is connected for 10 μm spacing, and not connected for 20 μm spacing. Solar cells may be made from all these regions.

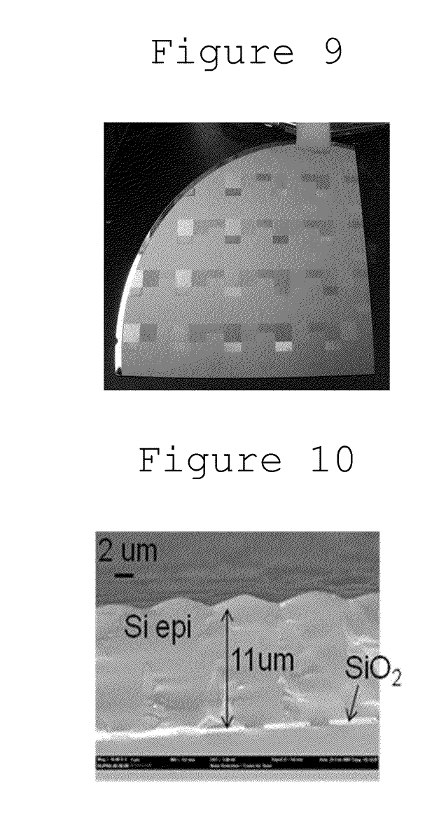

Referring to FIG. 9, the top view of a quarter of 8 inch wafer after the ELO growth is shown in a picture. Growth from one pattern was characterized by scanning electron microscopy (SEM), which is shown in FIG. 10. 800 nm SiO2 is used at the interface instead of the optimized reflector. The junction region width is 2 μm and the spacing is 5 μm. For the solar cells using this pattern and ELO growth, the best open circuit voltage may be about 544 mV for ELO structure and 600 mV for the planar structure. We assume that the recombination on the backside of the thin Si leads to the great loss of the voltage for the solar cells using ELO structure. A good surface passivation to the ELO solar cells may be used in order to achieve better voltage results.

According to a second exemplary embodiment, a thin silicon solar cell structure may be provided using silicon-on-insulator (SOI) technology with properties of high voltage in thin silicon designs with an epitaxial emitter. Design parameters may low rear and front surface recombination, low dark current and efficient light trapping. A patterned emitter area on a SOI substrate may be provided. The advantages of this design may be the passivation properties embedded in the buried oxide and the reduced junction area. With a uniform epitaxial emitter, the top contact shadowing can be designed to be 0%. Exemplary results show V_{oc}>525 mV and JSC>20 mA/cm2. This current design also demonstrates the effect of a smaller emitter area and reports higher performance parameters for reported silicon cells fabricated on SOI substrates.

SOI may provide potential of high V_{oc} thin silicon designs. The high performance thin crystalline silicon solar cell opportunity is based on high open circuit voltage (V_{oc}) due to low base recombination. Thin silicon solar cells can have higher voltages if there is low rear and front surface recombination. To achieve high voltages, a low dark current and low back surface recombination may be required.

Different approaches to thin cells grown on low cost substrates have been studied. Glass is a very low cost option but processing difficulties have shown it may not be the best choice. The use of silicon as the substrate has shown efficiencies of 12.7% with a 30 μm epitaxial layer. Thin cells with epitaxially grown base and emitters on a crystalline substrate demonstrated 14.2% efficient cells with a base thickness below 15 μm. Porous silicon has been used as an alternative for a reflector layer to improve light trapping. In SOI material, the buried oxide (BOx) may not only provide self passivation properties but may also provide optical properties that can be used to enhance the photovoltaic response. Exemplary embodiments may achiever efficiencies of 6 to 8% for 6 μm. thick layers with an active area contact of 4% to 40% of the cell area. Voltage and current are proportional to the epitaxial layer area coverage of cells which is evidence of reduced dark current in the emitter and some light reflection from the oxide.

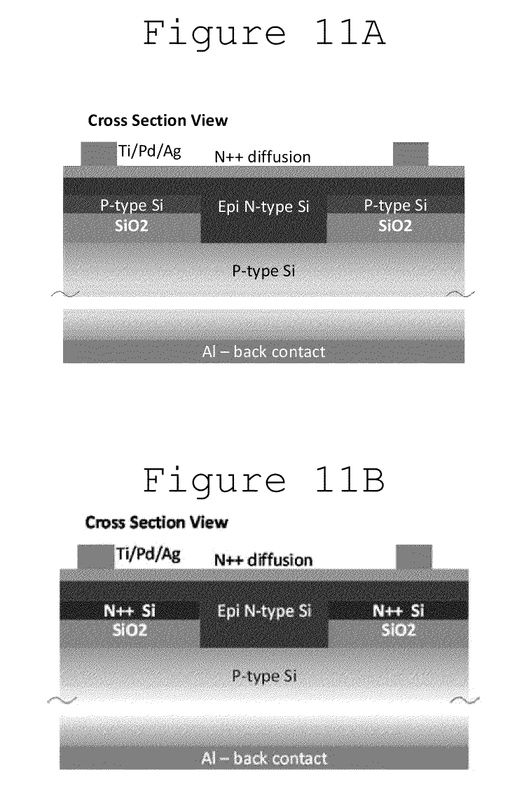

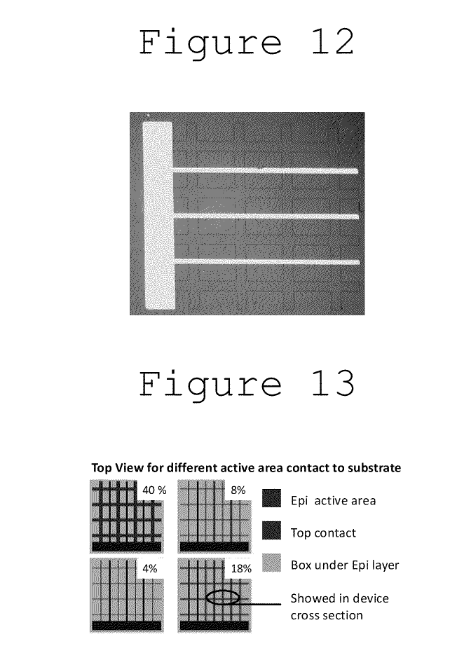

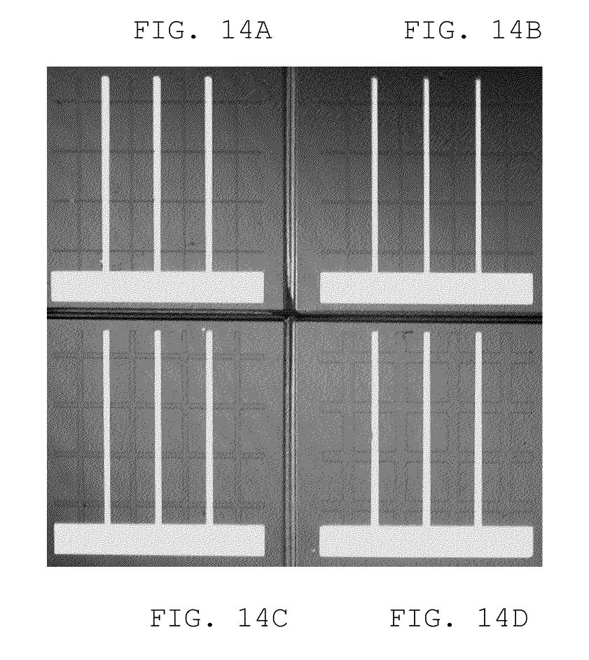

The use of SOI with a high performance device design may overcome difficulties of same surface contact designs. The substrate may be used as a base and the emitter may be epitaxially grown with different layouts and geometries as shown in FIGS. 11A and 11B. Other challenges such as carrier collection and lateral diffusion of minority carriers represent a cost in design and processing. With this configuration, the high quality BOx and top p-type layer surrounding the n-type emitter may act as a passivation and intermediate back surface field structures to improve the device performance. Improved carrier collection may be achieved with n+ diffusion on the grown emitter.

More than 700 mV are feasible for n-type active layers below 35 μm. The n-type epitaxial layer of good quality provides a uniform doping concentration and low defect density throughout all the emitter volume. This epitaxial emitter may overcome the complexity in doped junctions due to the presence of a doping profile that causes internal electric fields, dependence of diffusion length and mobility on the carrier concentration, band gap narrowing due to high doping. The injected current may be dependent on JOE, where the surface recombination velocity has to be kept low (SR<10³ cm/s) and the surface carrier concentration at the surface below 2×10¹⁹ cm⁻³.

The exemplary device may be based on a p-type silicon-on-insulator (SOI) substrate that is used to grow an n-type crystalline silicon emitter. The n-type layer thickness may be kept below 15 μm and therefore the active part of the cell will be retained in the front of the solar cell. Combined simulations and practical results have demonstrated a high performance solar cell using commercially available SOI substrates. One advantage of the SOI substrate may be the passivation properties embedded in the buried oxide that may provide a lower emitter and front surface recombination velocities. The starting point of the actively thin solar cells may be the silicon growth on available passivated substrates. The combination of simulations, improved fabrication technology, and low surface recombination demonstrates a path to high voltage, efficient thin crystalline silicon solar cells.

The fabrication process of the cell starts with the patterning of the active areas on the SOI substrate. Reactive ion etching may be used to remove the device layer and wet etching to remove the oxide and reach the base. An epitaxial layer may be grown with CVD techniques on the whole substrate. The additional n-type diffusion on top of the n-layer facilitates contact formation and reduces recombination at the metal-silicon interface. Referring to FIG. 15, different active area geometries are tested on the same substrate (including planar cells) to study 2D effects on the active area. The back contact may be evaporated aluminum; the top contact may be Ti/Pd/Ag.

Cells with different active area coverage (4%, 8%, 18%, 40%, 100%) may be fabricated with the same epitaxial layer growth process and using the same SOI substrate. All cells may have a standard DLAR (no additional passivation oxide) to increase for light trapping.

Results have shown V_{oc} above 525 mV for all grid epi-SOI cells compared to the planar cell fabricated on the same substrate which has a lower V_{oc}. The increase may be attributed to the J_{OE} reduction. The substrate used does not have the optimal doping concentration. Higher V_{oc} values may be achieved with a passivation layer, a thinner emitter, top contact annealing and the optimal substrate concentration. Short circuit current densities are above 20 mA/cm².

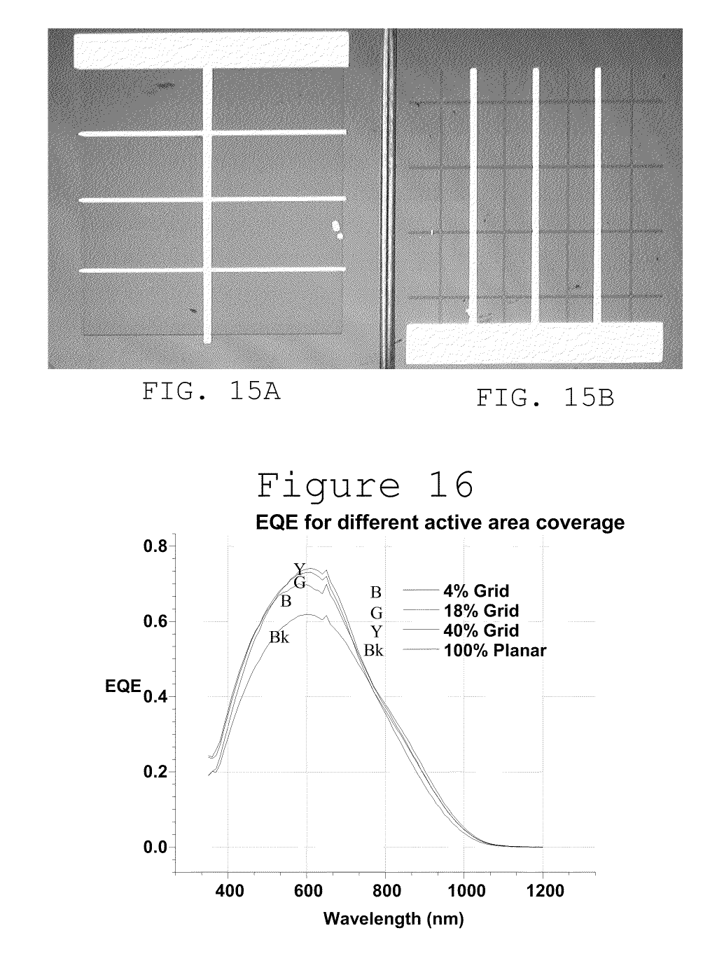

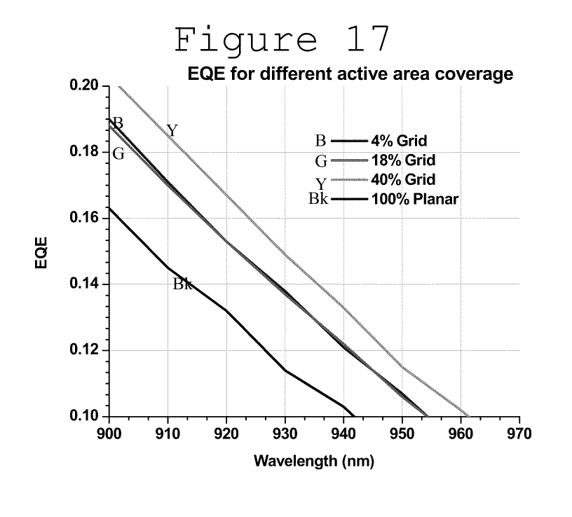

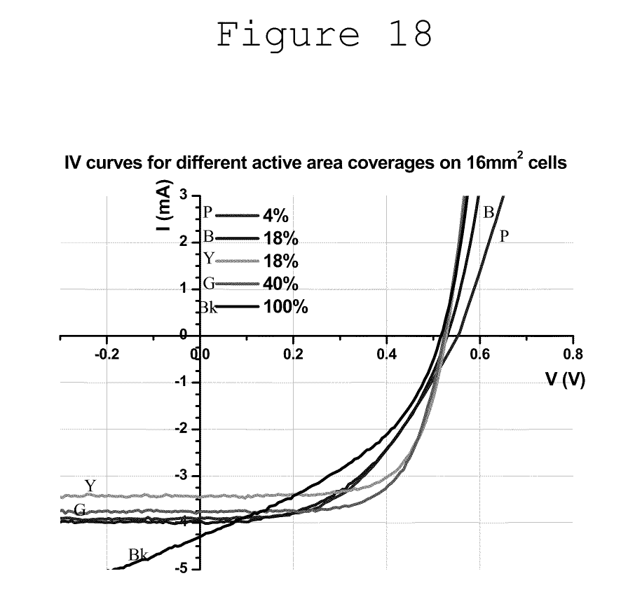

Referring to FIGS. 16 and 18, EQE measurements show there room for enhancement in the back surface of the cells, compared to a thin film behavior reported by Danos et al. Different active area coverage implies more or less BOx area in the device which demonstrates light trapping. The presented results show a grid shaped active contact to the substrate. Equivalent area coverage is being fabricated for isolated squares connected through the epitaxial layer only to study effects of defects on the vertical sidewalls due to etching steps, as well as the vertical and horizontal current flow from the whole epitaxial layer into the patterned contact through the emitter.

Factors that can lead to high V_{oc} in this solar cell are the low front surface recombination and high minority carrier lifetime. The achieved surface passivation reflects a large increase in open circuit voltage (larger than that of thick cells). A SINTON® WCT-120 lifetime tested was used to measure carrier lifetimes. The buried oxide in the SOI substrate acts as a back surface field and provides good isolation for adjacent cells. This novel design uses existing layers as potential barriers (BSF) in the solar cell.

Different layouts used for the active areas may show paths to reduced dark current. The reduced contact area through the substrate and an improved back surface recombination may result in higher V_{oc}. Random light trapping may be added to the top surface to increase absorption and current and are within the scope of the invention.

Other modifications and substitutions by one of ordinary skill in the art are considered to be within the scope of the present invention, which is not to be limited except by the following claims.

### ACKNOWLEDGEMENTS

This research was, in part, funded by the U.S. Government Defense Advanced Research Projects Agency under Agreement No.: HR0011-0709-0005. The views and conclusions contained in this document are those of the authors and should not be interpreted as representing the official policies, either express or implied, of the U.S. Government.

### REFERENCES

[1] A. Barnett, C. Honsberg, et al. High Performance Thin Silicon Solar Cells. 22nd European Photovoltaic Solar Energy Conference, September 2007.

[2] D. D. Rathman, D. J. Silversmith and J. A. Burns. Lateral Epitaxial Overgrowth of Silicon on SiO2. J. Electrochem. Soc.: SOLID-STATE SCIENCE AND TECHNOLOGY, Vol. 129, No. 10.

[3] T. Buck, A. Helfricht, et al. Crystalline Si Thin Film n-Type Solar Cells: A Screen Printed Rear Junction Approach. 22nd European Photovoltaic Solar Energy Conference, September 2007.

[4] F. Duerinckx, I. Kuzma Filipek, et al. Optical Path Length Enhancement For >13% Screenprinted Thin Film Silicon Solar Cells. 21st European Photovoltaic Solar Energy Conference, September 2006.

E. Schmich, et al. Improvement of Epitaxial Crystalline Silicon Thin-film Solar Cells at Fraunhofer ISE, IEEE 33rd PVSC (2008)

F. Duerinckx, et al. Optical path length enhancement for >13% screenprinted thin film silicon solar cells. 21st European PVSEC (2006)

R. Prinja, et al. Absorption enhancement in thin-film silicon solar cells in SOI configuration using physical and geometrical optics. IEEE 33rd PVSC. (2007)

L. Danos, G. Jones, R. Greef, T. Markvart. Ultra thin silicon solar cell: modeling and characterization. Phys. Stat. Sol. C. 1407-1410 (2008) Danos, et al, used a SOI substrate to grow n and p Si (0.2 μm) on the BOx in a lateral geometry. By only using the device layer, a very low current (0.065 mA) was achieved with n and p contacts on the top surface, using the BOx as a support layer and reflector.

The invention claimed is:

1. A thin silicon solar cell structure comprising:
a p+ type silicon substrate;
a dielectric layer disposed over the p+ type silicon substrate;
one or more trenches defined within the dielectric layer; and
a thin n− type silicon layer grown on the p+ type silicon substrate within the one or more trenches by epitaxial lateral overgrowth wherein a junction area of the solar cell is minimized within the trench.

2. The thin silicon solar cell structure of claim 1, wherein the p+ type silicon substrate is lattice matched with the n− type silicon layer.

3. The thin silicon solar cell structure of claim 1, wherein the one or more trenches has a width of less than 1 μm

4. The thin silicon solar cell structure of claim 1, wherein the dielectric layer is about 800 nm layer of Silicon Dioxide.

5. The thin silicon solar cell structure of claim 1, wherein the solar cell structure has a ratio of light generation area to junction area of about 10.

6. The thin silicon solar cell structure of claim 1, further comprises:
a double layer antireflection coating on the n type silicon layer.

7. The thin silicon solar cell structure of claim 1, wherein the one or more trenches are spaced about 10 μm apart.

8. A method for producing a thin silicon solar cell comprising:
providing p+ type silicon substrate;
thermally growing a layer of SiO2 over the p+ type silicon substrate;
etching one or more trenches defined within the SiO2 layer; and
depositing a thin n− type silicon layer on the p+ type silicon substrate within the one or more trenches with chemical vapor deposition by epitaxial lateral overgrowth wherein a junction area of the solar cell is produced and minimized within the trench.

9. The method for producing a thin silicon solar cell of claim 8, wherein the
p+ type silicon substrate is lattice matched with the n− type silicon layer.

10. The method for producing a thin silicon solar cell of claim 8, wherein the one or more trenches has a width of less than 1 μm.

11. The method for producing a thin silicon solar cell of claim 8, wherein the SiO2 layer is about 800 thick.

12. The method for producing a thin silicon solar cell of claim 8, wherein the solar cell structure has a ratio of light generation area to junction area of about 10.

13. The method for producing a thin silicon solar cell of claim 8, further comprises:
providing a double layer antireflection coating on the n type silicon layer.

14. A thin silicon solar cell structure comprising:
a p+ type silicon-on-insulator (SOI) substrate;
one or more trenches defined within a device layer and a dielectric layer of the silicon-on-insulator (SOI) substrate; and
a thin n− type silicon layer grown on silicon-on-insulator (SOI) substrate within the one or more trenches by epitaxial lateral overgrowth wherein a junction area of the solar cell is minimized within the trench.

15. The thin silicon solar cell structure of claim 14, wherein the
p+ type silicon substrate is lattice matched with the n− type silicon layer.

16. The thin silicon solar cell structure of claim 14, wherein the one or more trenches has a width of less than 1 μm

17. The thin silicon solar cell structure of claim 14, wherein the dielectric layer is about 800 nm thick.

18. The thin silicon solar cell structure of claim 14, wherein the solar cell structure has a ratio of light generation area to junction area of about 10.

19. The thin silicon solar cell structure of claim 14, further comprises a back contact of evaporated aluminum and a top contact of Ti/Pd/Ag.

20. The thin silicon solar cell structure of claim 14, wherein the grown n-type silicon layer provides additional n-type diffusion to the silicon-on-insulator (SOI) substrate.
